(19) United States
(12) Patent Application Publication
(10) Pub. No.: US 2025/0098171 A1
(43) Pub. Date: Mar. 20, 2025

(54) MEMORY DEVICE AND ELECTRONIC APPARATUS INCLUDING THE SAME

(71) Applicant: SAMSUNG ELECTRONICS CO., LTD., Suwon-si (KR)

(72) Inventors: Kyunghun KIM, Suwon-si (KR); Hoseok HEO, Suwon-si (KR); Sunho KIM, Suwon-si (KR); Seungyeul YANG, Suwon-si (KR); Minhyun LEE, Suwon-si (KR); Seokhoon CHOI, Suwon-si (KR)

(73) Assignee: SAMSUNG ELECTRONICS CO., LTD., Suwon-si (KR)

(21) Appl. No.: 18/885,031

(22) Filed: Sep. 13, 2024

(30) Foreign Application Priority Data
Sep. 14, 2023 (KR) 10-2023-0122660

(51) Int. Cl. H10B 43/30; H10B 43/27

(52) U.S. Cl. CPC H10B 43/30; H10B 43/27

(57) ABSTRACT

A memory device includes: a channel layer; a gate electrode spaced apart from the channel layer; and a multilayer charge trap layer disposed between the channel layer and the gate electrode, wherein the multilayer charge trap layer includes silicon oxynitride, the silicon oxynitride including gallium or silicon nitride including gallium.

### CROSS-REFERENCE TO RELATED APPLICATION

This application is based on and claims priority under 35 U.S.C. § 119 to Korean Patent Application No. 10-2023-0122660, filed on Sep. 14, 2023, in the Korean Intellectual Property Office, the disclosure of which is incorporated by reference herein in its entirety.

### BACKGROUND

### 1. Field

This disclosure relates to memory devices and electronic apparatuses including the memory devices.

### 2. Description of the Related Art

As hard disks of the related art have been replaced by solid state drives (SSDs), NAND flash memory devices, which are non-volatile memory devices, are becoming widely commercialized. Recently, as devices have become miniaturized and highly integrated, vertical type memory devices have been developed. In the vertical type memory devices, multiple memory cells are stacked in a direction perpendicular to a substrate. In vertical NAND flash memory devices, a charge transfer between the multiple memory cells may occur due to an increase in the number of stacked memory cells and a decrease in height, and the charge transfer may worsen the charge retention of the memory cells.

### SUMMARY

Provided are memory devices with improved charge retention performance of a charge trap layer (CTL) and electronic apparatuses including the memory devices.

Additional aspects will be set forth in part in the description which follows and, in part, will be apparent from the description, or may be learned by practice of the presented embodiments of the disclosure.

According to an aspect of the disclosure, a memory device includes: a channel layer; a gate electrode spaced apart from the channel layer; and a multilayer charge trap layer disposed between the channel layer and the gate electrode, wherein the multilayer charge trap layer includes silicon oxynitride, the silicon oxynitride including gallium or silicon nitride including gallium.

According to an aspect of the disclosure, a memory device includes: a substrate; and a plurality of memory cell arrays disposed on the substrate, wherein each of the plurality of memory cell arrays includes: a channel layer extending in a first direction; a plurality of gate electrodes spaced apart from the channel layer in a second direction different from the first direction, wherein the plurality of gate electrodes are alternately arranged in the first direction; and a multilayer charge trap layer disposed between the channel layer and the gate electrode, and wherein the multilayer charge trap layer includes silicon oxynitride, the silicon oxynitride including gallium or silicon nitride including gallium.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 illustrates a schematic cross-sectional view showing a memory device according to an embodiment;

FIG. 2 illustrates a schematic cross-sectional view showing a memory device according to another embodiment;

FIG. 3 illustrates a schematic cross-sectional view showing a memory device according to another embodiment;

FIG. 4 illustrates a schematic cross-sectional view showing a memory device according to another embodiment;

FIG. 5 illustrates a graph showing C-V characteristics of a charge trap layer according to the memory device of FIG. 1;

FIG. 6 illustrates a graph showing C-V characteristics of a charge trap layer according to the memory device of FIG. 2;

FIG. 7A illustrates a diagram showing an energy band diagram of a memory device according to a comparative example;

FIG. 7B illustrates a diagram showing an energy band diagram of a memory device according to an embodiment;

FIG. 8 illustrates a cross-sectional view showing a schematic structure of a memory device according to an embodiment;

FIG. 9 illustrates a perspective view showing a schematic structure of a memory cell array in the memory device of FIG. 8; and

FIG. 10 illustrates a diagram schematically showing a device architecture that may be applied to electronic apparatuses according to example embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, memory devices and electronic apparatuses including the same according to various embodiments will be described in detail with reference to the accompanying drawings. In the drawings, like reference numerals refer to like elements throughout, and sizes of elements in the drawings may be exaggerated for clarity and convenience of explanation. In addition, example embodiments may be variously modified and may be embodied in many different forms.

Hereinafter, when a position of an element is described using an expression “above” or “on”, the position of the element may include not only the element being “immediately on a contact manner” but also being on a non-contact manner”. The singular forms include the plural forms unless the context clearly indicates otherwise. When a part “comprises” or “includes” an element in the specification, unless otherwise defined, it is not excluding other elements but may further include other elements.

In the specification, the term “above” and similar directional terms may be applied to both singular and plural. With respect to operations that constitute a method, the operations may be performed in any appropriate sequence unless the sequence of operations is clearly described, and the operations may not necessarily be performed in the order of sequence.

Connecting lines or connecting members between the components shown in the drawings are merely illustrative of functional connections and/or physical or circuit connections, and in a practical device, the connections between the components may be represented by various functional connections, physical connections or circuit connections.

All examples or example terms are simply used to explain in detail the technical scope of the disclosure, and thus, the scope of the disclosure is not limited by the examples or the example terms as long as it is not defined by the claims.

The embodiments may be described and illustrated in terms of blocks, as shown in the drawings, which carry out a described function or functions. These blocks, which may be referred to herein as computing unit devices, memory unit devices, central processing units, or the like may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein). The circuits may, for example, be embodied in one or more semiconductor chips, or on substrate supports such as printed circuit boards and the like. Circuits included in a block may be implemented by dedicated hardware, or by a processor (e.g., one or more programmed microprocessors and associated circuitry), or by a combination of dedicated hardware to perform some functions of the block and a processor to perform other functions of the block. Each block of the embodiments may be physically separated into two or more interacting and discrete blocks. Likewise, the blocks of the embodiments may be physically combined into more complex blocks.

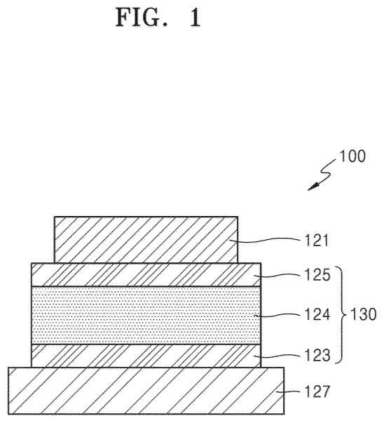

FIG. 1 illustrates a schematic cross-sectional view showing a memory device 100 according to an embodiment.

Referring to FIG. 1, the memory device 100 according to an embodiment may include a channel layer 127, a gate electrode 121 spaced apart from the channel layer 127, a multilayer charge trap layer 130 disposed between the channel layer 127 and the gate electrode 121 and including silicon oxynitride including gallium or silicon nitride including gallium.

The gate electrode 121 may be spaced apart from the channel layer 127. The gate electrode 121 may control the corresponding channel layer 127, and a word line may be electrically connected to the gate electrode 121. The gate electrode 121 may include, for example, a metal material having excellent electrical conductivity, such as gold (Au) or titanium (Ti), metal nitride, silicon doped with an impurity, or a two-dimensional conductive material. However, this is just an example, and the gate electrode 121 may include various other materials.

The channel layer 127 may include a semiconductor material. The channel layer 127 may include, for example, Si, Ge, SiGe, a Group III-V semiconductor, etc. Also, the channel layer 127 may include, for example, an oxide semiconductor, a nitride semiconductor, an oxynitride semiconductor, a 2D semiconductor material, quantum dots, or an organic semiconductor. Here, the oxide semiconductor may include, for example, InGaZnO, etc., the two-dimensional semiconductor material may include, for example, transition metal dichalcogenide (TMD) or graphene, and the quantum dot may include colloidal quantum dots (QD), nanocrystal structures, etc. However, these are merely examples, and embodiments of the disclosure are not limited thereto.

The channel layer 127 may further include a dopant. The dopant may include a p-type dopant or an n-type dopant. The p-type dopant may include, for example, a Group III element, such as B, Al, Ga, In, etc., and the n-type dopant may include a Group V element, such as P, As, Sb, etc.

In an embodiment, the multilayer charge trap layer 130 may be provided between the gate electrode 121 and the channel layer 127. The multilayer charge trap layer 130 may include multiple layers including a charge trap layer 124. For example, the multilayer charge trap layer 130 may include a first diffusion barrier layer 123 (disposed between the channel layer 127 and the charge trap layer 124), a charge trap layer 124, and a second diffusion barrier layer 125 (disposed between the gate electrode 121 and the charge trap layer 124), as shown in FIG. 1.

The charge trap layer 124 may store inflowing charges. Charges (e.g., electrons) existing in the channel layer 127 may flow into the charge trap layer 124 through a tunneling effect or the like. Charges flowing into the charge trap layer 124 may be fixed to the charge trap layer 124.

The charge trap layer 124 may include silicon oxynitride including gallium (Ga). Because the charge trap layer 124 includes gallium, charge retention of a memory cell may be improved. The content of gallium included in the charge trap layer 124 may be about 0.5 at % (atomic percent) or more and about 20 at % or less, but embodiments of the disclosure are not limited thereto. For example, the content of gallium included in the charge trap layer 124 may be about 8 at % or more and about 16 at % or less. Gallium and silicon in the charge trap layer 124 may be uniformly distributed within the charge trap layer 124 or may be distributed in a layer-by-layer (LBL) structure.

The charge trap layer 124 may include silicon nitride including gallium (Ga). The content of metal included in the charge trap layer 124 may be, for example, about 0.5 at % or more and about 20 at % or less. The content of metal included in the charge trap layer 124 may be, for example, about 8 at % or more and about 16 at % or less.

If the charge trap layer 124 includes silicon oxynitride (or silicon nitride) including gallium (Ga), the trap energy and trap density may be increased compared to an existing charge trap layer including only silicon oxynitride (or silicon nitride). The trap energy refers to a voltage barrier that electrons need to cross to move from one atom to another within a material, and the trap density refers to the number of trapped charges per unit volume.

The first diffusion barrier layer 123 may include silicon nitride or silicon oxynitride. A thickness of the first diffusion barrier layer 123 may be, for example, about 5 nm or less. The thickness of the first diffusion barrier layer 123 may be, for example, about 2 nm or less.

The second diffusion barrier layer 125 may include silicon nitride or silicon oxynitride. A thickness of the second diffusion barrier layer 125 may be, for example, about 5 nm or less. The thickness of the second diffusion barrier layer 125 may be, for example, about 2 nm or less.

The thicknesses of the first diffusion barrier layer 123 and the second diffusion barrier layer 125 may be different from each other, but embodiments of the disclosure are not limited thereto, and thus, the thicknesses may be the same. Materials of the first diffusion barrier layer 123 and the second diffusion barrier layer 125 may be the same, but embodiments of the disclosure are not limited thereto, and thus, the materials may be different.

For example, the charge trap layer 124 (included in the multilayer charge trap layer 130) may include gallium silicon oxynitride (GaSiON), and the first diffusion barrier layer 123 and the second diffusion barrier layer 125 may include silicon nitride (SiN). For example, the charge trap layer 124 (in the multilayer charge trap layer 130) may include GaSiON, and the first diffusion barrier layer 123 and the second diffusion barrier layer 125 may include silicon oxynitride (SiON). For example, the charge trap layer 124 (in the multilayer charge trap layer 130) may include gallium silicon nitrogen (GaSiN), and the first diffusion barrier layer 123 and the second diffusion barrier layer 125 may include SiN. For example, the charge trap layer 124 (in the multilayer charge trap layer 130) may include GaSiN, and the first diffusion barrier layer 123 and the second diffusion barrier layer 125 may include SiON, but embodiments of the disclosure are not limited thereto.

In the memory device 100 according to an embodiment, the charge trap layer 124 includes silicon oxynitride (or silicon nitride) including gallium (Ga), thereby increasing the trap energy and trap density. In addition, the charge trap layer 124 is provided between the first diffusion barrier layer 123 and the second diffusion barrier layer 125, thus, the deterioration of device characteristics due to gallium (Ga) diffusion may be prevented. Accordingly, a highly efficient memory device 100 may be implemented.

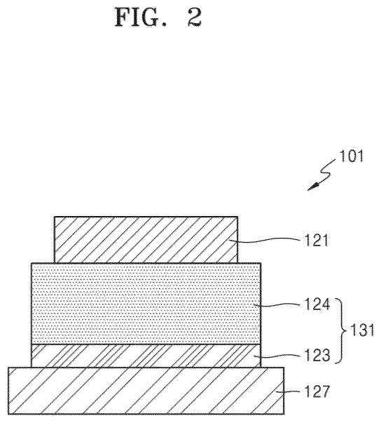

FIG. 2 illustrates a schematic cross-sectional view showing a memory device 101 according to another embodiment.

Referring to FIG. 2, the memory device 101 according to another embodiment includes a channel layer 127, a gate electrode 121 spaced apart from the channel layer 127, and a multilayer charge trap layer 131 disposed between the channel layer 127 and the gate electrode 121 and including silicon oxynitride including gallium or silicon nitride including gallium. In the description of FIG. 2, descriptions previously given with reference to FIG. 1 will be omitted.

The multilayer charge trap layer 131 may include a charge trap layer 124 and a first diffusion barrier layer 123 disposed between the channel layer 127 and the charge trap layer 124. The memory device 101 according to another embodiment may be the same as the memory device 100 of FIG. 1 except that the multilayer charge trap layer 131 does not include the second diffusion barrier layer 125.

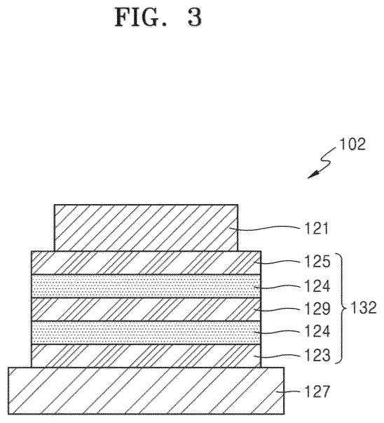

FIG. 3 illustrates a schematic cross-sectional view showing a memory device 102 according to another embodiment.

Referring to FIG. 3, the memory device 102 according to another embodiment includes a channel layer 127, a gate electrode 121 spaced apart from the channel layer 127, and a multilayer charge trap layer 132 disposed between the channel layer 127 and the gate electrode 121 and including silicon oxynitride including gallium or silicon nitride including gallium. In the description of FIG. 3, descriptions previously given with reference to FIG. 1 will be omitted.

The multilayer charge trap layer 132 may include a charge trap layer 124, a first diffusion barrier layer 123 disposed between the channel layer 127 and the charge trap layer 124, a second diffusion barrier layer 125 disposed between the gate electrode 121 and the charge trap layer 124, and a third diffusion barrier layer 129 disposed inside the charge trap layer 124.

As the third diffusion barrier layer 129 is disposed inside the charge trap layer 124, the charge trap layer 124 may have a multilayer structure. The third diffusion barrier layer 129 may include silicon nitride or silicon oxynitride. A thickness of the third diffusion barrier layer 129 may be, for example, about 5 nm or less. The thickness of the third diffusion barrier layer 129 may be, for example, about 2 nm or less.

The third diffusion barrier layer 129 may block diffusion of gallium (Ga) in the charge trap layer 124. Because the third diffusion barrier layer 129 is provided inside the charge trap layer 124, the deterioration of device characteristics due to the diffusion of gallium (Ga) in the charge trap layer 124 may be prevented, thereby implementing a highly efficient memory device 100.

The memory device 102 according to another embodiment may be the same as the memory device 100 of FIG. 1 except that the multilayer charge trap layer 132 further includes the third diffusion barrier layer 129.

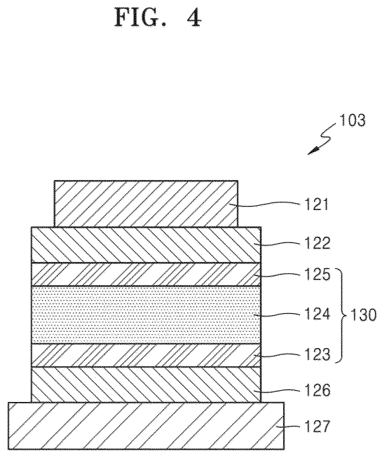

FIG. 4 illustrates a schematic cross-sectional view showing a memory device 103 according to another embodiment.

Referring to FIG. 4, the memory device 103 according to another embodiment may include a channel layer 127, a gate electrode 121 spaced apart from the channel layer 127, a multilayer charge trap layer 130 disposed between the channel layer 127 and the gate electrode 121 and including silicon oxynitride including gallium or silicon nitride including gallium, a tunneling barrier layer 126 disposed between the multilayer charge trap layer 130 and the channel layer 127, and a blocking insulating layer 122 disposed between the multilayer charge trap layer 130 and the gate electrode 121. In the description of FIG. 4, descriptions previously given with reference to FIG. 1 will be omitted.

The blocking insulating layer 122 may perform a barrier function to prevent charge movement between the charge trap layer 124 and the gate electrode 121. The blocking insulating layer 122 may include, for example, silicon oxide or metal oxide, but embodiments of the disclosure are not limited thereto. The tunneling barrier layer 126 is a layer through which tunneling of charges occurs. The tunneling barrier layer 126 may include, for example, silicon oxide or metal oxide.

The memory device 103 may be the same as the memory device 100 of FIG. 1 except that the memory device 103 further includes the blocking insulating layer 122 and the tunneling barrier layer 126. The multilayer charge trap layer 130 is shown as including the charge trap layer 124, the first diffusion barrier layer 123, and the second diffusion barrier layer 125, but embodiments of the disclosure are not limited thereto. The multilayer charge trap layer 130 may be the same as the multilayer charge trap layer 131 of FIG. 2 or the multilayer charge trap layer 132 of FIG. 3.

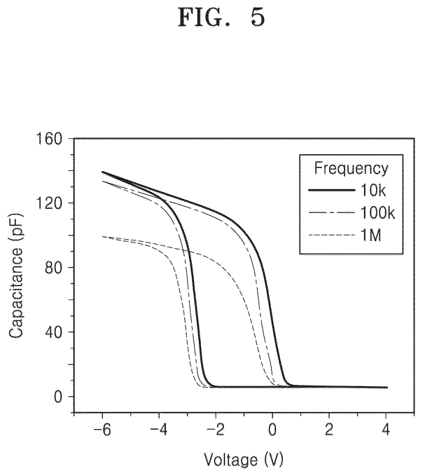

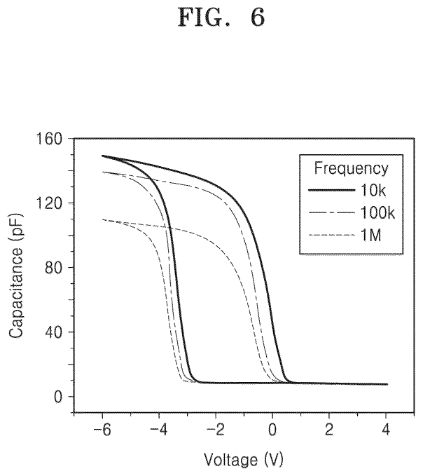

FIG. 5 is a graph showing C-V characteristics of the charge trap layer 124 according to the memory device 100 of FIG. 1, and FIG. 6 is a graph showing C-V characteristics of the charge trap layer 124 according to the memory device 101 of FIG. 2.

FIG. 5 shows measuring results regarding the C-V characteristics according to an applied voltage frequency (f) when the charge trap layer 124 is formed between the first diffusion barrier layer 123 and the second diffusion barrier layer 125.

FIG. 6 shows measuring results regarding the C-V characteristics according to an applied voltage frequency (f) when the first diffusion barrier layer 123 is formed under the charge trap layer 124.

Referring to FIGS. 5 and 6, it may be seen that when a negative voltage is applied to the gate electrode 121, a capacitance increases, and when a positive voltage is applied to the gate electrode 121, the capacitance decreases. In other words, it may be seen that on/off characteristics of the memory device are clear. Through this, it may be seen that because the memory devices 100 and 101 include diffusion barrier layers 123 and 125, the gallium diffusion of the charge trap layer 124 may be effectively blocked.

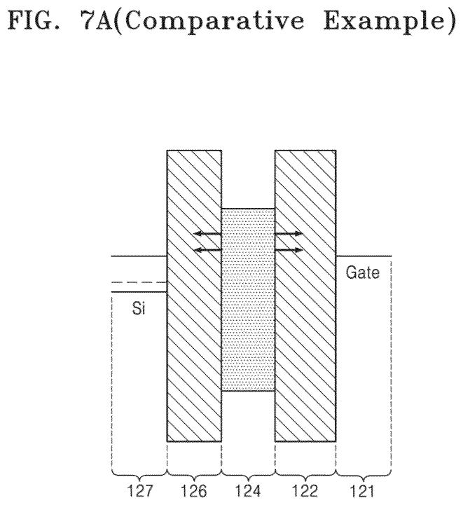

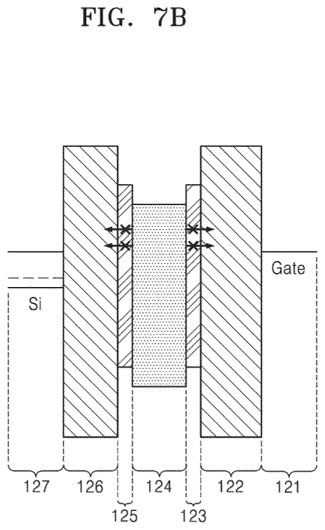

FIG. 7A illustrates an energy band diagram of a memory device according to a comparative example (related art).

Referring to FIG. 7A, the memory device according to the comparative example is configured of a gate electrode 121, a blocking insulating layer 122 provided corresponding to the gate electrode 121, a charge trap layer 124, a tunneling barrier layer 126, and a channel layer 127.

In an energy band diagram, an upper part of each box representing the blocking insulating layer 122, the charge trap layer 124, the tunneling barrier layer 126, and the channel layer 127 denotes a conduction band minimum (CBM), and a lower part of each box denotes a valence band maximum (VBM).

The charge trap layer 124 of the memory device according to the comparative example includes silicon oxynitride (or silicon nitride) containing gallium, thus, the charge trap layer 124 has a lower CBM, a lower VBM, and a lower trap level than the first diffusion barrier layer 123 and the second diffusion barrier layer 125 including silicon nitride or silicon oxynitride. In other words, the charge trap layer according to an embodiment has a higher trap energy than an existing charge trap layer including silicon nitride. However, as gallium (Ga) included in the charge trap layer 124 diffuses, deterioration of the memory device may occur. Such gallium diffusion may occur, for example, in a process of heat treatment during manufacturing the memory device, and if the diffused gallium flows into the channel layer 127, abnormal C-V characteristics may appear.

FIG. 7B illustrates a diagram showing an energy band diagram of a memory device according to an embodiment.

Referring to FIG. 7B, the memory device includes a gate electrode 121, a blocking insulating layer 122 provided corresponding to the gate electrode 121, a first diffusion barrier layer 123, a charge trap layer 124, a second diffusion barrier layer 125, a tunneling barrier layer 126, and a channel layer 127.

In the energy band diagram, an upper part of each box representing the blocking insulating layer 122, the first diffusion barrier layer 123, the charge trap layer 124, the second diffusion barrier layer 125, the tunneling barrier layer 126, and the channel layer 127 denotes a CBM, and a lower part of each box denotes a VBM.

Because the charge trap layer 124 includes silicon oxynitride (or silicon nitride) including gallium, the charge trap layer 124 has a higher trap energy than an existing charge trap layer including silicon nitride, thereby implementing a highly efficient memory device 100.

In addition, gallium (Ga) diffusion of the charge trap layer 124 may be blocked by forming the first diffusion barrier layer 123 between the blocking insulating layer 122 and the charge trap layer 124, and the second diffusion barrier layer 125 between the tunneling barrier layer 126 and the charge trap layer 124. In other words, it is possible to prevent performance degradation of a memory device due to gallium diffusion.

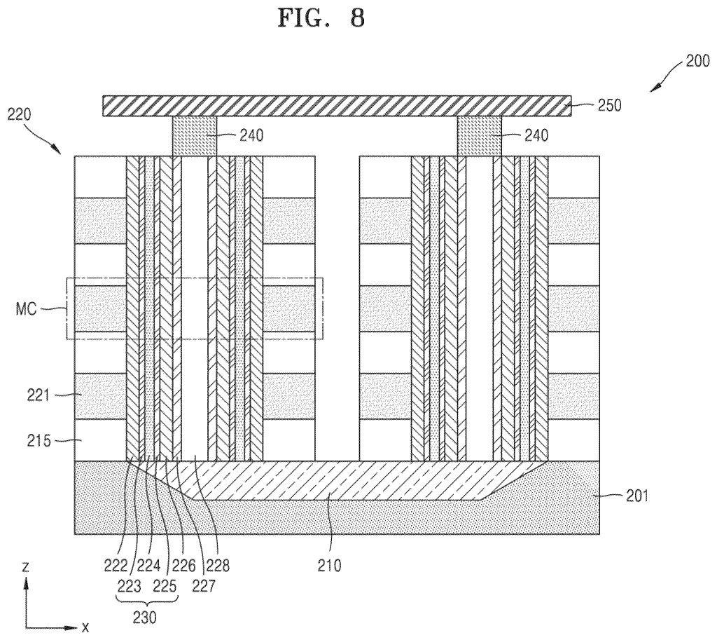

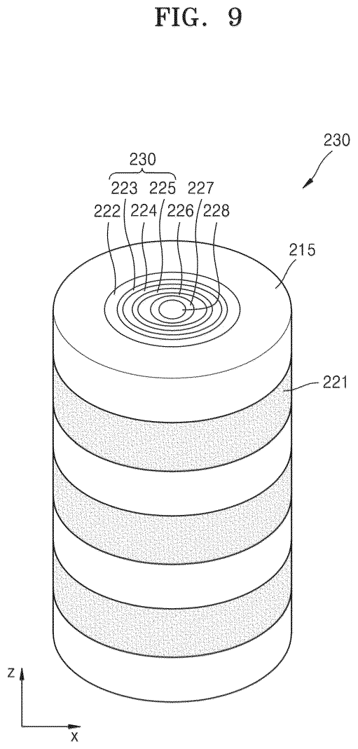

FIG. 8 illustrates a schematic cross-sectional view showing a structure of a memory device 200 according to an embodiment. FIG. 9 illustrates a schematic perspective view showing a structure of a memory cell array 220 provided in the memory device 200 of FIG. 8.

According to an embodiment, the memory device may be a charge trap-based flash NAND device.

Referring to FIG. 8, the memory device 200 includes a substrate 201 and a plurality of memory cell arrays 220 provided on the substrate 201.

A channel layer 227, a predetermined gate electrode 221 spaced apart from the channel layer 227, a blocking insulating layer 222 provided corresponding to the gate electrode 221, a charge trap layer 224 disposed between the channel layer 227 and the gate electrode 221, a first diffusion barrier layer 223 disposed between the gate electrode 221 and the charge trap layer 224, a second diffusion barrier layer 225 disposed between the channel layer 227 and the charge trap layer 224, a tunneling barrier layer 226, and a filling insulating layer 228 form one memory cell MC, and the memory cell array 220 includes a plurality of cells MC arranged in one direction.

The gate electrode 221, the blocking insulating layer 222, the first diffusion barrier layer 223, the charge trap layer 224, the second diffusion barrier layer 225, the tunneling barrier layer 226, and the channel layer 227 may be substantially the same as each of the gate electrode 121, the blocking insulating layer 122, the first diffusion barrier layer 123, the charge trap layer 124, the second diffusion barrier layer 125, the tunneling barrier layer 126, and the channel layer 227 described with reference to FIGS. 1 to 4.

The memory device 200 may also include a common source region 210 provided on the substrate 201, on which a plurality of memory cell arrays 220 are disposed, a drain 240 provided on the memory cell array 220, and a bit line 250 provided on the drain 240.

Each memory cell array 220 may be provided to extend in a direction perpendicular to the substrate 201 (a z-axis direction in FIG. 8). The plurality of memory cell arrays 220 may be arranged in various shapes on the substrate 201. The memory cell array 220 may have a cylindrical shape, but embodiments of the disclosure are not limited thereto, and may, for example, have a square pillar shape. Although two memory cell arrays 220 are shown in the drawing, this is an example, and the number of memory cells MC included in the memory cell array 220 is also an example. A plurality of memory cell arrays 220 including an arbitrary number of memory cells MC may be two-dimensionally arranged in X and Y directions.

The substrate 201 may include various materials. For example, the substrate 201 may include a single crystal silicon substrate, a compound semiconductor substrate, or a silicon on insulator (SOI) substrate, but embodiments of the disclosure are not limited thereto. Additionally, the substrate 201 may further include an impurity region by doping, electronic devices, such as transistors, or a peripheral circuit that selects and controls memory cells that store data.

On the substrate 201, interlayer insulating layers 215 and the gate electrodes 221 may be alternately stacked in a direction perpendicular to the substrate 201. Each interlayer insulating layer 215 and each gate electrode 221 may be provided side by side on the substrate 201.

The substrate 201 may include a silicon material doped with a first type impurity. The substrate 201 may include, for example, a silicon material doped with a p-type impurity. The substrate 201 may be, for example, a p-type well. However, the substrate 201 is not limited to p-type silicon.

The common source region 210 may be provided on the substrate 201. The common source region 210 may have a second type that is different from that of the substrate 201. The common source region 210 may have, for example, an n-type. However, the common source region 210 is not limited to the n-type.

A drain 240 may be provided on the memory cell array 220. The drain 240 may include, for example, a silicon material doped to a second type impurity. For example, the drain 240 may include a silicon material doped to an n-type.

A bit line 250 may be provided on the drain 240. The drain 240 and the bit line 250 may be connected through a contact plug.

The memory cell array 220 may include the channel layer 227 extending in a first direction (i.e., z-axis direction), the plurality of gate electrodes 221 arranged to be spaced apart from the channel layer 227 in a second direction (i.e., an x-axis direction) different from the first direction and alternately arranged in the first direction perpendicular to the substrate 201, the blocking insulating layer 222 sequentially provided between the gate electrodes 221 and the channel layer 227 in perpendicular to the substrate 201, a multilayer charge trap layer 230, and the tunneling barrier layer 226. Here, each of the blocking insulating layer 222, the multilayer charge trap layer 230, the tunneling barrier layer 226, and the channel layer 227 is arranged to extend in a direction perpendicular to the substrate 201 (i.e., the first direction), and may be shared by multiple memory cells.

The plurality of gate electrodes 221 are arranged to be spaced apart in the first direction. The number of gate electrodes 221 shown is illustrative and is not limited to the number shown. The number of the plurality of gate electrodes 221 may correspond to the number of memory cells MC individually controlled in the memory device 200, and may on/off control the corresponding memory cells MC according to an applied voltage. The gate electrode 221, for example, may be connected to a word line, and thus, a voltage that turns the memory cell MC on or off may be applied through the word line.

If a predetermined voltage is applied to the gate electrode 221 corresponding to each memory cell MC, charges flowing between the source and drain in the channel layer 227 corresponding to the gate electrode 221 pass through the tunneling barrier layer 226 and are trapped in the charge trap layer 224, and thus, information may be stored in the memory cell MC.

For example, when a memory cell MC to be written is selected, a region of the channel layer 227 corresponding to the selected memory cell MC is turned on, and a voltage that causes charges to move from the channel layer 227 to the charge trap layer 224 through the tunneling barrier layer 226 is applied to the gate electrode 221. The unselected memory cell MC turns on a region corresponding to the channel layer 227, but a voltage at which charges do not move from the channel layer 227 to the charge trap layer 224 is applied to the gate electrode 221. In this way, a current flow is formed through the channel layer 227, and charge trapping may be achieved only in the charge trap layer 224 corresponding to the selected memory cell MC. In this way, information of 1 or 0 may be recorded depending on charge trap of the charge trap layer 224 of each memory cell MC.

The interlayer insulating layer 215 may serve as a spacer layer for insulation between the gate electrodes 221. The interlayer insulating layer 215 may include, for example, silicon oxide, silicon nitride, etc., but embodiments of the disclosure are not limited thereto.

Channel holes penetrating through the interlayer insulating layers 215 and the gate electrodes 221 are formed in a direction perpendicular to the substrate 201 (the z-axis direction). For example, the channel holes may be formed to have a circular cross-section.

The blocking insulating layer 222, the multilayer charge trap layer 230, the tunneling barrier layer 226, and the channel layer 227 are sequentially provided on an inner wall of the channel hole. Here, each of the blocking insulating layer 222, the multilayer charge trap layer 230, the tunneling barrier layer 226, and the channel layer 227 may be formed to have a cylindrical shape extending in a direction perpendicular to the substrate 201. The filling insulating layer 228 may be provided to fill the channel hole inside the channel layer 227. For example, the filling insulating layer 228 may include, but is not limited to, silicon oxide or air.

The blocking insulating layer 222 may be provided on the inner wall of the channel hole to contact the interlayer insulating layers 215 and the gate electrodes 221. The blocking insulating layer 222 may perform a barrier function to prevent charge movement between the charge trap layer 224 and the gate electrode 221. The blocking insulating layer 222 may include, for example, silicon oxide or metal oxide, but is not limited thereto. The tunneling barrier layer 226 may be provided between the multilayer charge trap layer 230 and the channel layer 227. The tunneling barrier layer 226 is a layer through which charge tunneling occurs and may include, for example, silicon oxide or metal oxide, but is not limited thereto.

The multilayer charge trap layer 230 provided between the gate electrode 221 and the channel layer 227 may include the charge trap layer 224, the first diffusion barrier 223 (disposed between the gate electrode 221 and the charge trap layer 224), and the second diffusion barrier layer 225 (disposed between the channel layer 227 and the charge trap layer 224). However, embodiments of the disclosure are not limited thereto. For example, the multilayer charge trap layer 230 may be the same as one of the multilayer charge trap layers 130 and 132 described with reference to FIGS. 1 and 3.

The memory devices 100, 101, 102, 103, and 200 described above may be used to store data in various electronic apparatuses.

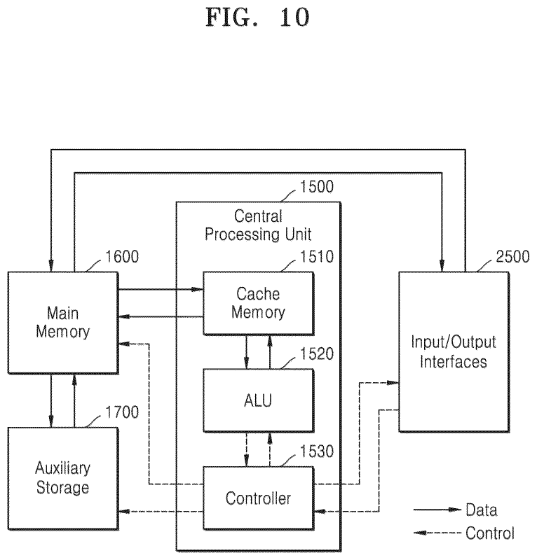

FIG. 10 illustrates a diagram schematically showing a device architecture that may be applied to electronic apparatuses according to example embodiments.

Referring to FIG. 10, a central processing unit (CPU) 1500 may include a cache memory 1510, an arithmetic logic unit (ALU) 1520, and a controller 1530, and the cache memory 1510 may include a static random access memory (SRAM). Separately from the CPU 1500, a main memory 1600 and an auxiliary storage 1700 may be provided. The main memory 1600 may include a DRAM device, and the auxiliary storage 1700 may include the memory devices 100, 101, 102, 103, and 200 described above. In some cases, the device architecture may be implemented in a form in which computing unit devices and memory unit devices are adjacent to each other on one chip without distinction of sub-units. As shown in FIG. 10, input/output interfaces 2500 (e.g., a keyboard, a mouse, a display/screen, etc.) may be operatively connected to the controller 1530 and the main memory 1600 to exchange data or control signals.

According to the disclosed embodiment, the memory device has a charge trap layer disposed between a first diffusion barrier layer and a second diffusion barrier layer, thereby preventing deterioration of device characteristics due to diffusion of gallium (Ga) in a charge trap layer.

The memory device according to an embodiment and the electronic apparatus including the same include a multilayer charge trap layer, thereby preventing deterioration of device characteristics due to diffusion of gallium (Ga) in a charge trap layer. Memory devices and electronic apparatuses including the same have been described with reference to the embodiments shown in the drawings. However, it will be understood by those of ordinary skill in the art that various changes in form and details may be made therein without departing from the spirit and scope of the disclosure. Therefore, the embodiments should be considered in descriptive sense only and not for purposes of limitation. The scope of the disclosure is defined not by the detailed description of the disclosure but by the appended claims, and all differences within the scope will be construed as being included in the disclosure.

Embodiments described herein may be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A memory device comprising:
a channel layer;
a gate electrode spaced apart from the channel layer; and
a multilayer charge trap layer disposed between the channel layer and the gate electrode,
wherein the multilayer charge trap layer comprises silicon oxynitride, the silicon oxynitride comprising gallium or silicon nitride comprising gallium.

2. The memory device of claim 1, wherein the multilayer charge trap layer further comprises:
a charge trap layer; and
a first diffusion barrier layer disposed between the channel layer and the charge trap layer.

3. The memory device of claim 1, wherein the multilayer charge trap layer further comprises:
a charge trap layer;
a first diffusion barrier layer disposed between the channel layer and the charge trap layer; and
a second diffusion barrier layer disposed between the gate electrode and the charge trap layer.

4. The memory device of claim 3, wherein each of the first diffusion barrier layer and the second diffusion barrier layer includes silicon nitride or silicon oxynitride.

5. The memory device of claim 4, wherein the charge trap layer includes gallium silicon oxynitride (GaSiON), and
wherein each of the first diffusion barrier layer and the second diffusion barrier layer includes silicon nitride (SiN).

6. The memory device of claim 3, wherein each of the first diffusion barrier layer and the second diffusion barrier layer has a thickness of 2 nm or less.

7. The memory device of claim 1, wherein the multilayer charge trap layer further includes:
a charge trap layer;
a first diffusion barrier layer disposed between the channel layer and the charge trap layer;
a second diffusion barrier layer disposed between the gate electrode and the charge trap layer; and
a third diffusion barrier layer disposed inside the charge trap layer.

8. The memory device of claim 7, wherein the third diffusion barrier layer includes silicon nitride or silicon oxynitride.

9. The memory device of claim 7, wherein the third diffusion barrier layer has a thickness of 2 nm or less.

10. The memory device of claim 1, further comprising a tunneling barrier layer disposed between the multilayer charge trap layer and the channel layer.

11. The memory device of claim 1, further comprising a blocking insulating layer disposed between the multilayer charge trap layer and the gate electrode.

12. A memory device comprising:
a substrate; and
a plurality of memory cell arrays disposed on the substrate,
wherein each of the plurality of memory cell arrays includes:
a channel layer extending in a first direction;
a plurality of gate electrodes spaced apart from the channel layer in a second direction different from the first direction, wherein the plurality of gate electrodes are alternately arranged in the first direction; and
a multilayer charge trap layer disposed between the channel layer and the gate electrode, and
wherein the multilayer charge trap layer comprises silicon oxynitride, the silicon oxynitride comprising gallium or silicon nitride comprising gallium.

13. The memory device of claim 12, wherein the multilayer charge trap layer further comprises:
a charge trap layer; and
a first diffusion barrier layer disposed between the channel layer and the charge trap layer.

14. The memory device of claim 12, wherein the multilayer charge trap layer further comprises:
a charge trap layer;
a first diffusion barrier layer disposed between the channel layer and the charge trap layer; and
a second diffusion barrier layer disposed between the gate electrode and the charge trap layer.

15. The memory device of claim 14, wherein each of the first diffusion barrier layer and the second diffusion barrier layer includes silicon nitride or silicon oxynitride.

16. The memory device of claim 15, wherein the charge trap layer includes gallium silicon oxynitride (GaSiON), and
wherein each of the first diffusion barrier layer and the second diffusion barrier layer includes silicon nitride (SiN).

17. The memory device of claim 14, wherein each of the first diffusion barrier layer and the second diffusion barrier layer has a thickness of two (2) nm or less.

18. The memory device of claim 12, wherein the multilayer charge trap layer further comprises:
a charge trap layer;
a first diffusion barrier layer disposed between the channel layer and the charge trap layer;
a second diffusion barrier layer disposed between the gate electrode and the charge trap layer; and
a third diffusion barrier layer disposed inside the charge trap layer.

19. The memory device of claim 12, further comprising a tunneling barrier layer disposed between the multilayer charge trap layer and the channel layer.

20. The memory device of claim 12, further comprising a blocking insulating layer disposed between the multilayer charge trap layer and the gate electrode.
